(19) United States
(12) Patent Application Publication
(10) Pub. No.: US 2014/0158407 A1
(43) Pub. Date: Jun. 12, 2014

(54) PRINTED CIRCUIT BOARD WITH VISIBLE TRIANGULAR SHAPED TRACES

(71) Applicant: Zhen Ding Technology Co., Ltd., Tayuan (TW)

(72) Inventor: MING-JAAN HO, Tayuan (TW)

(73) Assignee: ZHEN DING TECHNOLOGY CO., LTD., Tayuan (TW)

(21) Appl. No.: 14/078,544

(22) Filed: Nov. 13, 2013

(30) Foreign Application Priority Data
Dec. 6, 2012 (CN) 2012105187814

(51) Int. Cl. H05K 1/02

(52) U.S. Cl. CPC H05K 1/0298
USPC 174/251

(57) ABSTRACT

A printed circuit board includes a transparent base layer, a conductive trace layer, and a transparent cover layer. The conductive trace layer is formed on a first surface of the base layer, and includes two conductive pads and a grid-shaped conductive trace pattern. the grid-shaped conductive trace pattern includes a plurality of conductive traces, the conductive traces form a plurality of strips connected one by one, each strip includes a plurality of triangles arranged in a line, each two adjacent triangles in a same strip have a same side, each two adjacent triangles in different strips have a same side, two distal ends of each strip are connected to the two conductive pads respectively. The transparent cover layer s the grid-shaped conductive trace pattern and parts of the first surface without forming the conductive trace layer.

### BACKGROUND

1. Technical Field

The present disclosure relates to a printed circuit board (PCB).

2. Description of Related Art

In a PCB with circuit visible, a width of traces is usually miniaturized to increase the transparence of the PCB. Yet, slim traces are easy to be peeled off or broken, thus rendering the PCB useless.

Therefore, it is desirable to provide a PCB which can overcome the shortcomings mentioned above.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic view of a PCB according to a first embodiment of the present disclosure.

FIG. 2 is a sectional view taken along II-II line of the PCB of FIG. 1.

FIG. 3 is a schematic view of a PCB according to a second embodiment of the present disclosure.

### DETAILED DESCRIPTION

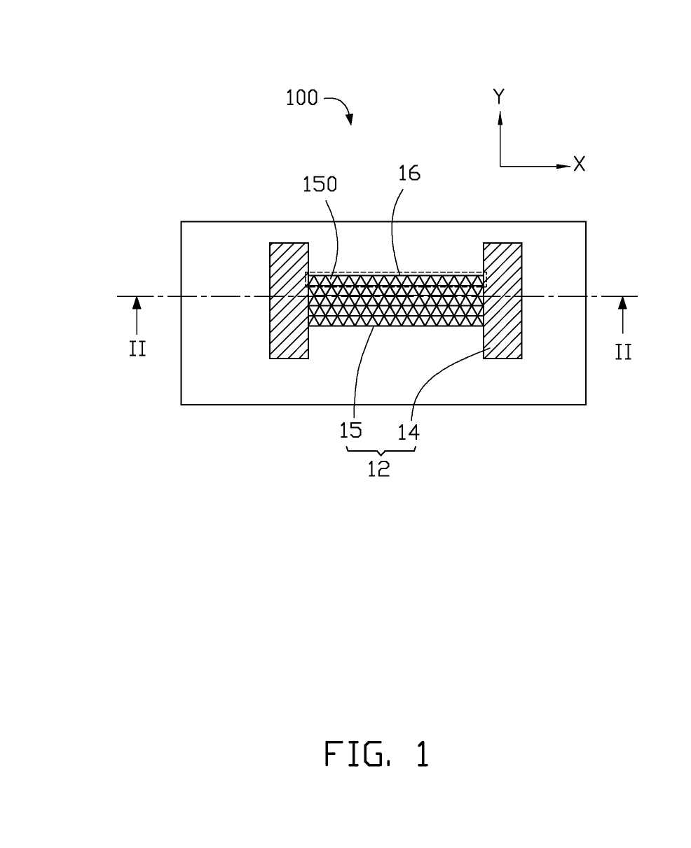

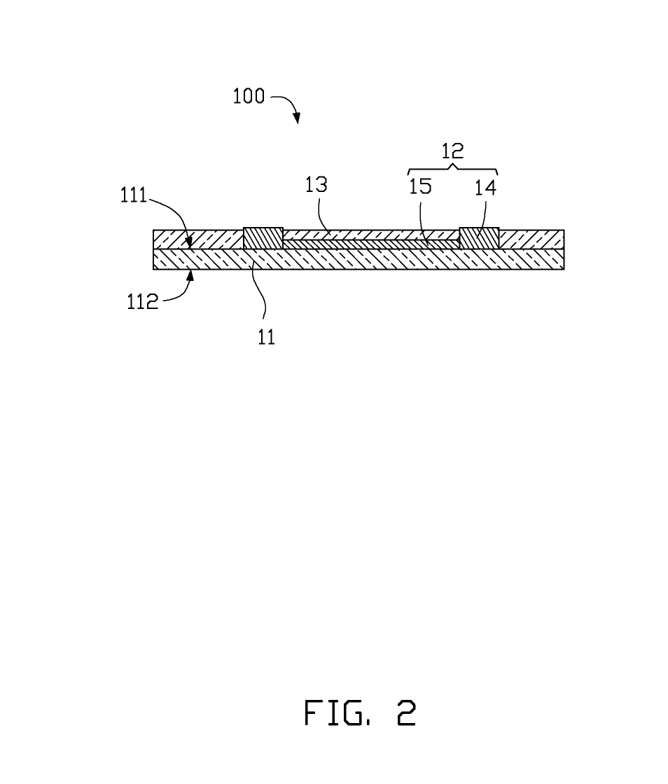

Referring to FIGS. 1 and 2, a PCB 100 according to a first embodiment of the present disclosure is shown. The PCB 100 includes a transparent base layer 11, a conductive trace layer 12, and a transparent cover layer 13.

The transparent base layer 11 includes a first surface 111 and a second surface 112 opposite to the first surface 111. The conductive trace layer 12 is formed on the first surface 111. The conductive trace layer 12 includes two conductive pads 14 and a grid-shaped conductive trace pattern 15 electrically connected between the two conductive pads 14. The two conductive pads 14 are configured for electrically connecting to electronic components. The transparent cover layer 13 covers the grid-shaped conductive pattern 15 and the first surface 111 exposed relative to the conductive trace layer 12. The two conductive pads 14 are exposed from the transparent cover layer 13. The transparent base layer 11 and the transparent cover layer 13 are made of transparent soft resin, such as polyethylene terephthalate (PET), polyethylene naphthalate (PEN), polyimide (PI), or transparent rigid epoxy resin. In this embodiment, the PCB 100 is a rigid and flex PCB and is made by semi-additive process.

The grid-shaped conductive trace pattern 15 includes a number of crossed conductive traces forming a number of triangles 150. The triangles 150 includes a number of strips 16 connected one by one (one of the strips 16 is shown in a dashed box of FIG. 1). Each strip 16 includes a number of triangles 150 arranged in a line. Each two adjacent triangles 150 in a same strip 16 have a same side, and each two adjacent triangles 150 in different strips 16 have a same side. Two distal ends of each strip 16 are connected to the two conductive pads 14 respectively. An X-axis is defined extending through centers of the two conductive pads 14, and a Y-axis is defined perpendicular to the X-axis parallel to the first surface 111. In this embodiment, each strip 16 extends along the X-axis, a number of the strips 16 are arranged along the Y-axis, and the triangles 150 are equilateral triangles.

A width, or a thickness of the traces of the grid-shaped conductive trace pattern 15 is preferably in a range of 10 μm (micrometer) to 15 μm. A side length of the triangles 150 is in a range of 500 μm to 1000 μm.

The grid-shaped conductive trace pattern 15 includes a number of strips 16. Even one of the strips 16 or some of the triangles 150 peel off or break, the two conductive pads 14 can be electrically connected by other strips 16 and other triangles 150. In this way, the yield rate for manufacturing the PCB 100 is increased, and the width of the traces can be reduced to enhance the transparency of the PCB 100 without affecting the function of the PCB 100. In this disclosure, the width of the traces can be less than 15 μm. Yet, in a prior art, the width of the traces must be larger than 15 μm to ensure the PCB is useful.

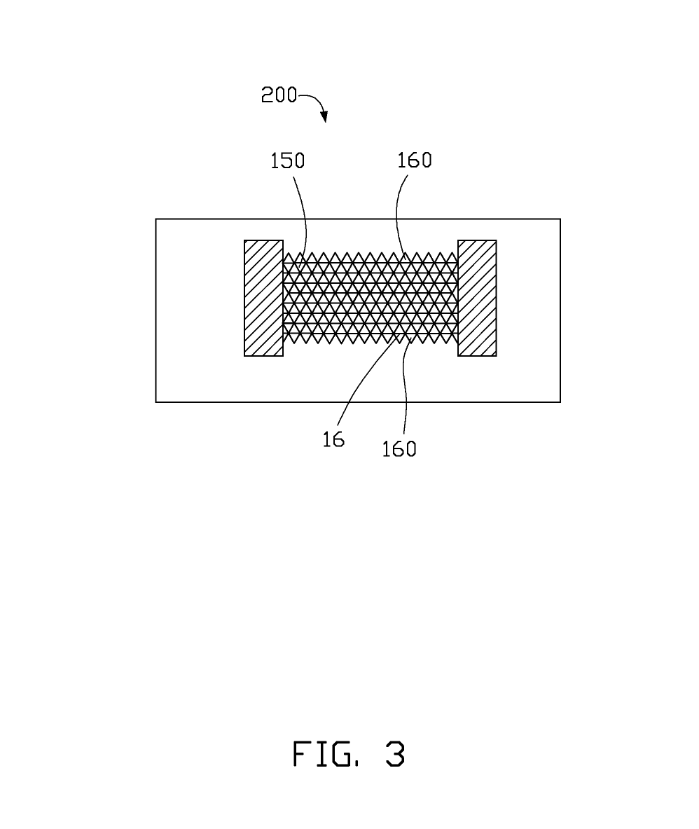

Referring to FIG. 3, a PCB 200 according to a second embodiment is disclosed. The PCB 200 is similar to the PCB 100, except that the PCB 200 further includes two rows of triangles 160 adjacent to two outermost strips 16. Each row of triangles 160 is serrate-shaped. Each triangle 160 and a triangle 150 adjacent to the triangle 160 have a same side.

It will be understood that the above particular embodiments are shown and described by way of illustration only. The principles and the features of the present disclosure may be employed in various and numerous embodiments thereof without departing from the scope of the disclosure. The above-described embodiments illustrate the scope of the disclosure but do not restrict the scope of the disclosure.

What is claimed is:

1. A printed circuit board (PCB) comprising:
a transparent base layer comprising a first surface and a second surface opposite to the first surface;
a conductive trace layer formed on the first surface, and comprising two conductive pads and a grid-shaped conductive trace pattern, the grid-shaped conductive trace pattern comprising a plurality of conductive traces, the conductive traces forming a plurality of strips connected one by one, each strip comprising a plurality of triangles arranged in a line, each two adjacent triangles in a same strip having a same side, each two adjacent triangles in different strips having a same side, two distal ends of each strip connected to the two conductive pads respectively; and
a transparent cover layer covering the grid-shaped conductive trace pattern and parts of the first surface without forming the conductive trace layer.

2. The PCB of claim 1, wherein the transparent base layer and the transparent cover layer are made of selected from the group consisting of polyethylene terephthalate (PET), polyethylene naphthalate (PEN), polyimide (PI), and rigid epoxy resin.

3. The PCB of claim 1, wherein the triangles are equilateral triangles.

4. The PCB of claim 1, wherein the grid-shaped conductive trace pattern further comprises two rows of first triangles formed adjacent to two outermost of the strips, each row of the first triangles is serrate shaped, and each first triangle and one of the triangle adjacent to the first triangle have a same side.

5. The PCB of claim 1, wherein the plurality of strips are arranged along a direction perpendicular to a direction extending through centers of the two conductive pads.

6. The PCB of claim 1, wherein a width of the conductive traces is in a range of 10 μm (micrometer) to 15 μm.

7. The PCB of claim 6, wherein a side length of the triangles is in a range of 500 μm to 1000 μm.

8. The PCB of claim 1, wherein the two conductive pads are exposed from the transparent cover layer.
